(19) United States
(12) Patent Application Publication
(10) Pub. No.: US 2007/0013047 A1
(43) Pub. Date: Jan. 18, 2007

(54) Enhanced PGA Interconnection

(76) Inventor: Edgardo R Hortaleza, Garland, TX (US)

Correspondence Address: Sam Tung;Texas Instruments Incorporation, P.O. Box 655474, M8 3999, Dallas, TX, 75265, US

(21) Appl. No.: 11/532,643

(22) Filed: Sep. 18, 2006

Related U.S. Application Data
(62) Division of application No. 10/903,749, filed on Jul. 30, 2004.

(51) Int. Cl. H01L 23/48

(52) U.S. Cl. 257/697; 257/E23.068

(57) ABSTRACT

A pin grid array package, comprising a substrate, a chip mounted abutting said substrate, and a plurality of pins electrically connected to said substrate, each pin comprising a substantially flat disc at an end of the pin opposite the substrate, said disc oriented perpendicular to said pin. The substrate contains metal traces to transfer electrical signals between the chip and each pin, wherein said disc is usable to provide each pin an electrical connection to a structure external to the package.

This application is a divisional of co-pending application, Ser. No. 10/903,749 filed Jul. 30, 2004.

### BACKGROUND

A pin grid array (“PGA”) package is a type of chip package wherein metal conducting pins are located external to the package and usually are arranged in concentric squares. These pins conduct electrical signals between the chip inside the package and a structure (e.g., printed circuit board) external to the chip package that is coupled to the pins. PGA packages are considerably useful for chips having a substantial number of pins (e.g., a microprocessor). An exemplary PGA package 100 having multiple pins 102 is illustrated in FIG. 1a.

A PGA package generally is coupled to a device external to the package by inserting the pins into sockets found on the external device. By inserting the pins into these sockets, electrical pathways are established for communication between the chip inside the PGA package and the device having the socket. Referring to FIG. 1b, for example, a PGA package 100 comprising multiple pins 102 is shown adjacent an application board 104 comprising a socket 106. By inserting the pins 102 into the socket 106, a chip (not shown) inside the PGA package 100 is able to communicate with the application board 104 by way of electrical signals transmitted through the pins 102 and the socket 106. FIG. 1c shows a side/front view of a portion of the PGA package 100 comprising a pin 102 mounted onto a package substrate 108. The substrate 108 is an element of the PGA package 100 upon which the chip is mounted. The substrate 108 routes electrical signals between the chip and the pins 102 by way of metal traces (not shown) etched into the substrate 108.

While these conventional pin and socket combinations present substantially reliable interconnections between chips and application boards, sockets are considerably expensive. The process of implementing a socket onto an application board also is expensive and time-consuming.

### BRIEF SUMMARY

The problems noted above are solved in large part by a pin grid array package whose pins may be electrically connected to an application board without using a socket. An exemplary embodiment may comprise a substrate, a chip mounted abutting said substrate, and a plurality of pins electrically connected to said substrate, each pin comprising a substantially flat disc at an end of the pin opposite the substrate, said disc oriented perpendicular to said pin. The substrate contains metal traces to transfer electrical signals between the chip and each pin, wherein said disc is usable to provide each pin an electrical connection to a structure external to the package.

### BRIEF DESCRIPTION OF THE DRAWINGS

For a detailed description of exemplary embodiments of the invention, reference will now be made to the accompanying drawings in which:

FIG. 1a shows a pin grid array (“PGA”) package;

FIG. 1b shows the PGA package having pins that may be inserted into a socket on an application board;

FIG. 1c shows an individual pin of the PGA package of FIG. 1b;

FIG. 2a shows a front view and side view of an individual pin of a PGA package in accordance with a preferred embodiment of the invention;

FIG. 2b shows a bottom view of the pin of FIG. 2a in accordance with a preferred embodiment of the invention;

FIG. 3 shows the pin of FIGS. 2a and 2b electrically connected to an application board in accordance with embodiments of the invention; and

FIG. 4 shows a process implementing the connections shown in FIG. 3, in accordance with embodiments of the invention.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

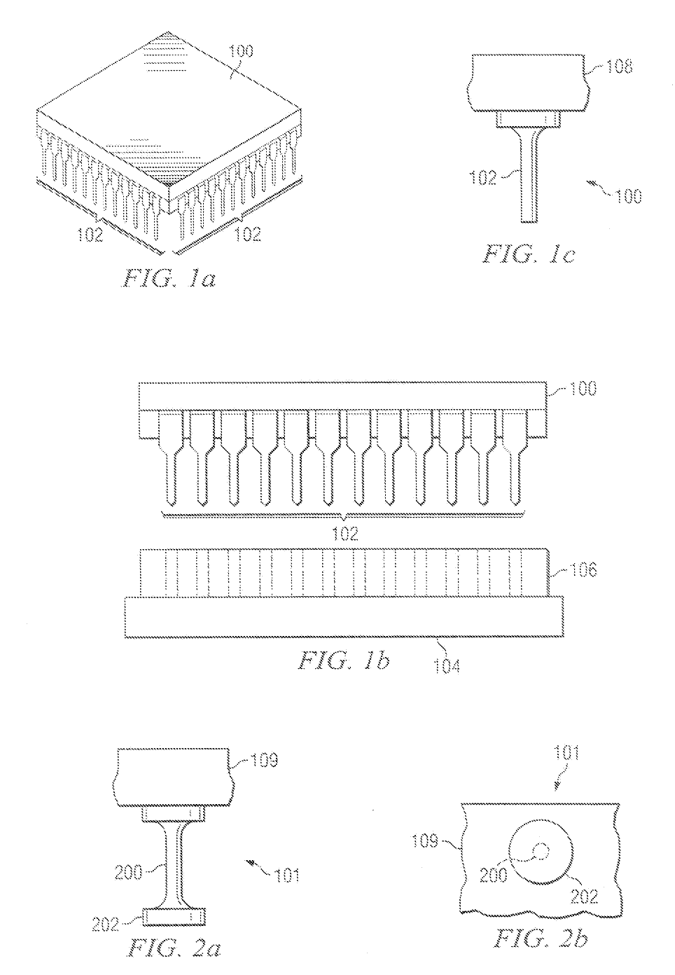

Presented herein is a design for a PGA package pin that may be electrically connected directly to an application board (i.e., a printed circuit board), thus eliminating the need for sockets on the application board. FIG. 2a shows a front/side view and FIG. 2b shows a bottom view of a PGA package 101 comprising a pin 200 with such a design. Specifically, the pin 200 is mounted abutting a substrate 109 of the PGA package 101. The pin 200 comprises a disc 202 on a side of the pin 200 opposite the substrate 109. The disc 202 enables the pin 200 to be electrically connected (e.g., using a solder reflow process) to an application board without using a socket, thus substantially reducing production costs. The disc 202 preferably may be circular in shape, although the scope of disclosure is not limited to any particular shape. Discs of any shape (e.g., rectangular, irregular) may be used. Although FIGS. 2a and 2b show only a single pin 200, the PGA package 1 01 may comprise multiple pins 200, as necessary. Although the pins (including discs) may be of any size, they preferably are of a size that would prevent short circuits between multiple pins soldered onto the application board. Thus, in at least some embodiments, pins on a substrate with a high pin pitch may be of a lesser size than pins on a substrate with a low pin pitch.

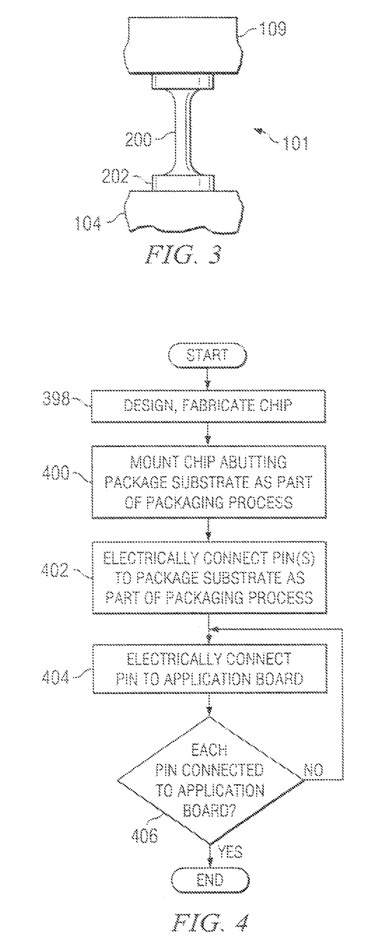

FIG. 3 shows the PGA package 101 with the pin 200 electrically connected to an application board 104. The electrical connection may be established by way of a solder reflow process, a welding process or any other suitable process. Data may be transferred between the substrate 109 and the application board 104 by way of this electrical connection.

FIG. 4 describes a process by which the pin/application board connection of FIG. 3 may be implemented. The process may begin with the design and fabrication of the chip that is to be housed within the PGA package 101 (block 398). The chip then is subjected to a packaging process during which, among other things, the chip is mounted abutting the package substrate 109 (block 400). During this packaging process, the pin 200 (along with multiple additional pins as necessary) is electrically connected to the substrate 109 using any suitable connection process, such as a reflow process, welding process or bracing process (block 402). After the packaging process is complete, the pin 200 is electrically connected to the application board 104, preferably by way of a solder reflow process, although any suitable process may be used (block 404). Each of the remaining pins of the PGA package 101 is individually connected to the application board 104 in succession (block 406), although, in some embodiments, some or all of the pins may be electrically connected to the application board 104 simultaneously.

Solder balls generally are used to establish electrical connections between two devices during a surface mount assembly process (i.e., solder reflow process). For example, a chip may be mounted abutting a substrate using such solder balls (e.g., during a “flip chip” process). Solder balls typically are made of tin lead or lead-free material, which often melts during a solder reflow process, thereby reducing the standoff height between the two devices. A reduced standoff height usually results in reduced reliability levels due to an increase in solder joint stress. Accordingly, the pin 200 (including the disc 202) may be fabricated using a material that is not susceptible to such problems, such as nickel, gold or copper. Some or all of the remaining pins on the PGA package 100 also may be fabricated using similar materials. Thus, when the pin 200 is electrically connected to the application board 104 using a solder reflow process, the standoff height is maintained and there is no reduction in reliability level. The chemical composition of the pin 200 preferably may be physically compatible with lead-free materials.

The pin 200 may be manufactured in a manner similar to PGA pins common in the art; however, manufacturing molds or other such structures used to manufacture these common PGA pins may differ from manufacturing molds or structures used to manufacture the pin 200 having the disc 202. For example, a manufacturing mold used to manufacture the pin 200 may have a flared disc shape at one end to allow for the fabrication of the disc 202, whereas a mold used to manufacture a common PGA pin may not have such a flared disc shape. Such a manufacturing technique is simply exemplary of a variety of manufacturing methods. The scope of disclosure is not limited to these manufacturing techniques. Any suitable manufacturing or fabrication technique that produces the pin 200 and the disc 202 contained therein may be used.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method, comprising:
electrically connecting a pin to a package substrate, said pin comprising a substantially flat disc at an end of the pin opposite the substrate; and
electrically connecting the pin to a device external to the package.

2. The method of claim 1, wherein electrically connecting the pin to the package substrate comprises electrically connecting a pin to a package substrate, said pin comprising a substantially flat, circular disc at an end of the pin opposite the substrate.

3. The method of claim 1, wherein electrically connecting the pin to the package substrate comprises electrically connecting a pin to a package substrate, said pin comprising a substantially flat, irregularly-shaped disc at an end of the pin opposite the substrate.

4. The method of claim 1, wherein electrically connecting the pin to the package substrate comprises electrically connecting a pin to a package substrate, said pin comprising a substantially flat disc at an end of the pin opposite the substrate, said disc oriented perpendicular to the pin.

5. The method of claim 1, wherein electrically connecting the pin to the device external to the package comprises electrically connecting the pin to an application board.

6. The method of claim 1, wherein electrically connecting the pin to the package substrate comprises electrically connecting the pin to the package using either a solder reflow process, a welding process or a bracing process.

7. The method of claim 1, wherein electrically connecting the pin to the package substrate comprises electrically connecting to the package substrate either a nickel pin, a gold pin or a copper pin.
